(19) United States
(12) Patent Application Publication
(10) Pub. No.: US 2007/0277866 A1
(43) Pub. Date: Dec. 6, 2007

(54) Thermoelectric nanotube arrays

(75) Inventors: Melissa Suzanne Sander, Schenectady, NY (US); Fred Sharifi, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company, Schenectady, NY (US)

(21) Appl. No.: 11/444,016

(22) Filed: May 31, 2006

(51) Int. Cl. H01L 35/02; H01L 35/34

(52) U.S. Cl. 136/230; 136/201

(57) ABSTRACT

In some embodiments, the present invention is directed to thermoelectric devices comprising thermoelectric elements comprising nanotubes of thermoelectric material. The present invention is also directed to methods of making such thermoelectric elements and devices, particularly wherein the nanotubes are formed electrochemically in templates. The present invention is also directed to systems and applications incorporating and using such devices, respectfully.

### TECHNICAL FIELD

The present invention relates generally to heat transfer and power generation devices, and more particularly, to solid-state heat transfer devices.

### BACKGROUND INFORMATION

Heat transfer devices may be used for a variety of heating/cooling and power generation/heat recovery systems, such as refrigeration, air conditioning, electronics cooling, industrial temperature control, waste heat recovery, and power generation. These heat transfer devices are also scalable to meet the thermal management needs of a particular system and environment. However, existing heat transfer devices, such as those relying on refrigeration cycles, are environmentally unfriendly, have limited lifetime, and are bulky due to mechanical components such as compressors and the use of refrigerants.

In contrast, solid-state heat transfer devices offer certain advantages, such as, high reliability, reduced size and weight, reduced noise, low maintenance, and a more environmentally friendly device. For example, thermoelectric devices transfer heat by flow of electrons and holes through pairs of p-type and n-type semiconductor thermoelements forming structures that are connected electrically in series and thermally in parallel. However, due to the relatively high cost and low efficiency of the existing thermoelectric devices, they are restricted to small scale applications, such as automotive seat coolers, generators in satellites and space probes, and for local heat management in electronic devices.

At a given operating temperature, the heat transfer efficiency of thermoelectric devices depends on the Seebeck coefficient, electrical conductivity and the thermal conductivity of the thermoelectric materials employed for such devices. Such efficiency can be characterized by the figure-of-merit, ZT, which is defined in Equation 1 as:

ZT=S²σT/k (1)

where S is the thermopower or Seebeck coefficient,

σ is the electrical conductivity,

k is the thermal conductivity, and

T is the absolute temperature.

To compete with conventional refrigerators and generators, one must develop materials with ZT>3. In five decades, however, the room-temperature ZT of bulk semiconductors has increased only marginally, from about 0.6 to 1. The challenge lies in the fact that variables S, σ, and k are all interdependent—changing one alters the others, thereby making optimization extremely difficult.

Many techniques have been used to increase the heat transfer efficiency of the thermoelectric devices through improving the figure-of-merit value, many of these focusing on low dimensional or nanoscale thermoelectric structures (see, e.g., Majumdar “Thermoelectricity in Semiconductor Nanostructures,” Science vol. 303, pp. 777-778, 2004). For example, in some heat transfer devices two-dimensional superlattice thermoelectric materials have been employed for increasing the figure-of-merit value of such devices (see, e.g., Venkatasubramanian et al. “Thin-film thermoelectric devices with high room-temperature figures of merit,” Nature vol. 413, pp. 597-602, 2001; Harman et al. “Quantum Dot Superlattice Thermoelectric Materials and Devices,” Science vol. 297, pp. 2229-2232, 2002). Such devices may require deposition of two-dimensional superlattice thermoelectric materials through techniques, such as molecular beam epitaxy or vapor phase deposition. Other devices have employed one-dimensional nanorod or nanowire systems (see U.S. patent application Ser. No. 11/138,615, filed May 26, 2005). However, in order to improve thermoelectric nanowire properties relative to the bulk, it is generally necessary to decrease the wire diameter below 20 nm, and for some materials below 5 nm. Unfortunately, it is quite challenging to fabricate nanowire arrays that are also thick (tens to hundreds of microns) with controlled composition along the length of the wire, as is necessary for efficient thermoelectrics.

Accordingly, there remains a need to provide a thermal transfer device that has enhanced efficiency achieved through improved figure-of-merit of the thermal transfer device, and for methods of making such a device that are economical. It would also be advantageous to provide a device that is scalable to meet the thermal management needs of a particular system and environment.

### BRIEF DESCRIPTION OF THE INVENTION

In some embodiments, the present invention is directed to thermoelectric devices comprising thermoelectric elements comprising nanotubes of thermoelectric material. The present invention is also directed to methods of making such thermoelectric elements and devices, particularly wherein the nanotubes are formed electrochemically in templates. The present invention is also directed to systems and applications incorporating and using such devices, respectively.

In some such above-mentioned embodiments, the present invention is directed to a thermoelectric device comprising: (a) a first thermally conductive substrate having a first patterned electrode disposed thereon; (b) a second thermally conductive substrate having a second patterned electrode disposed thereon, wherein the first and second thermally conductive substrates are arranged such that the first and second patterned electrodes form an electrically continuous circuit; (c) a plurality of thermoelectric elements positioned between the first and second patterned electrodes, wherein the thermoelectric elements comprise a plurality of nanotube structures of doped semiconducting material; and (d) a joining material disposed between the plurality of thermoelectric elements and at least one of the first and second patterned electrodes.

In some such above-described embodiments, the present invention is directed to a method for fabricating a thermoelectric element, the method comprising the steps of: (a) providing a substantially planar porous template comprising a plurality of pores, the pores being largely perpendicular to the plane of the template and comprising pore walls that extend the thickness (i.e., height) of the template; (b) uniformly depositing a metal layer over porous template such that the pore walls are coated; (c) using the coated pore walls to electrochemically deposit thermoelectric material as nanotubes within the pore walls; and (d) selectively etching away the metal layer to yield a plurality of thermoelectric nanotubes in the template.

The foregoing has outlined rather broadly the features of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagrammatical illustration of a system having a thermal transfer device, in accordance with some embodiments of the present invention;

FIG. 2 is a diagrammatical illustration of a power generation system having a thermal transfer device, in accordance with some embodiments of the present invention;

FIG. 3 is a cross-sectional view of a thermal transfer unit, in accordance with some embodiments of the present invention;

FIG. 4 illustrates, in stepwise and plan-view fashion, a method for making thermoelectric nanotube arrays, in accordance with some embodiments of the present invention;

FIG. 5 illustrates, in stepwise and cross-sectional fashion, a method for making thermoelectric nanotube arrays, in accordance with some embodiments of the present invention;

FIG. 6 illustrates, in stepwise and perspective-view fashion, a method for making thermoelectric nanotube arrays, in accordance with some embodiments of the present invention;

FIG. 7 is a diagrammatical side view illustrating an assembled module of a thermal transfer device having a plurality of thermal transfer units, in accordance with some embodiments of the present invention; and

FIG. 8 is a perspective view illustrating a module having an array of thermal transfer devices, in accordance with some embodiments of the present invention.

### DETAILED DESCRIPTION OF THE INVENTION

In some embodiments, the present invention is directed to thermoelectric devices comprising thermoelectric elements comprising nanotubes of thermoelectric material. The present invention is also directed to methods of making such thermoelectric elements and devices, particularly wherein the nanotubes are formed electrochemically in templates. The present invention is also directed to systems and applications incorporating and using such devices, respectfully.

With respect to such above-mentioned thermoelectric elements and devices comprising nanotubes, the most important nanostructure dimension is the tube wall thickness, so that the outer tube diameter is not as critical and the arrays are simpler to fabricate than very narrow diameter nanowires. Methods in accordance with some embodiments of the present invention allow for excellent control over the tube wall thickness and composition. This approach is also suitable for manufacturing dense arrays of nanotubes over large areas, which is critical for the fabrication of practical devices. In addition, a wide range of thermoelectric nanotube materials can be fabricated, allowing one to tailor the material choice to a particular temperature range of interest.

In the following description, specific details are set forth such as specific quantities, sizes, etc. so as to provide a thorough understanding of embodiments of the present invention. However, it will be obvious to those skilled in the art that the present invention may be practiced without such specific details. In many cases, details concerning such considerations and the like have been omitted inasmuch as such details are not necessary to obtain a complete understanding of the present invention and are within the skills of persons of ordinary skill in the relevant art.

Referring to the drawings in general, it will be understood that the illustrations are for the purpose of describing a particular embodiment of the invention and are not intended to limit the invention thereto.

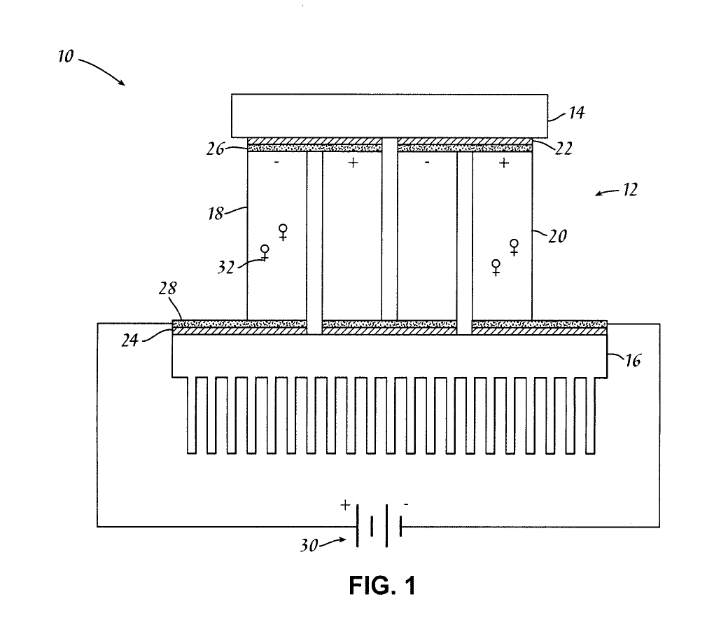

FIG. 1 illustrates a system 10 having a plurality of thermal transfer devices in accordance with certain embodiments of the present invention. As illustrated, the system 10 includes a thermal transfer module such as represented by reference numeral 12, comprised of thermoelectric elements 18 and 20, that transfers heat from an area or object 14 to another area or object 16 that may function as a heat sink for dissipating the transferred heat. Thermal transfer module 12 may be used for generating power or to provide heating or cooling of the components. Further, the components for generating heat such as object 14 may generate low-grade heat or high-grade heat. As will be discussed below, the first and second objects 14 and 16 may be components of a vehicle, or a turbine, or an aircraft engine, or a solid oxide fuel cell, or a refrigeration system. It should be noted that, as used herein the term “vehicle” may refer to a land-based, an air-based or a sea-based means of transportation. In this embodiment, the thermal transfer module 12 includes a plurality of thermoelectric devices. Note that generally such thermal transfer modules comprise at least a pair of such thermoelements; one being an n-type semiconductor leg, and the other being a p-type semiconductor leg.

In the above-described embodiment, the thermoelectric module 12 comprises n-type semiconductor legs 18 and p-type semiconductor legs 20 that function as thermoelements, whereby heat generated by charge transport is transferred away from the object 14 towards the object 16. In this embodiment, the n-type and p-type semiconductor legs (thermoelements) 18 and 20 are disposed on patterned electrodes 22 and 24 that are coupled to the first and second objects 14 and 16, respectively. In certain embodiments, the patterned electrodes 22 and 24 may be disposed on thermally conductive substrates (not shown) that may be coupled to the first and second objects 14 and 16. Further, interface layers 26 and 28 are employed to electrically connect pairs of the n-type and p-type semiconductor legs 18 and 20 on the patterned electrodes 22 and 24.

In the embodiment described above and as depicted in FIG. 1, the n-type and p-type semiconductor legs 18 and 20 are coupled electrically in series and thermally in parallel. In certain embodiments, a plurality of pairs of n-type and p-type semiconductors 18 and 20 may be used to form thermocouples that are connected electrically in series and thermally in parallel for facilitating the heat transfer. In operation, an input voltage source 30 provides a flow of current through the n-type and p-type semiconductors 18 and 20. As a result, the positive and negative charge carriers transfer heat energy from the first electrode 22 onto the second electrode 24. Thus, the thermoelectric module 12 facilitates heat transfer away from the object 14 towards the object 16 by a flow of charge carriers 32 between the first and second electrodes 22 and 24. In certain embodiments, the polarity of the input voltage source 30 in the system 10 may be reversed to enable the charge carriers to flow from the object 16 to the object 14, thus heating the object 14 and causing the object 14 to function as a heat sink. As described above, the thermoelectric module 12 may be employed for heating or cooling of objects 14 and 16. Further, the thermoelectric module 12 may be employed for heating or cooling of objects in a variety of applications such as air conditioning and refrigeration systems, cooling of various components in applications such as an aircraft engine, or a vehicle, or a turbine and so forth. In certain embodiments, the thermoelectric device 12 may be employed for power generation by maintaining a temperature gradient between the first and second objects 14 and 16, respectively that will be described below.

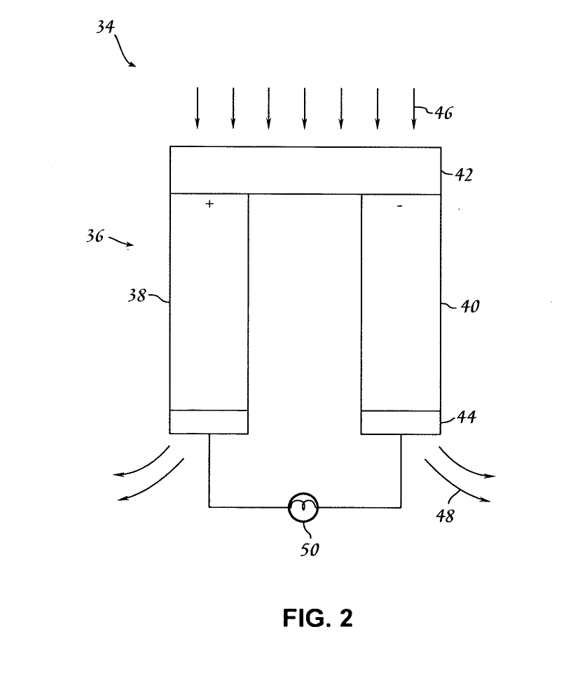

FIG. 2 illustrates a power generation system 34 having a thermal transfer device 36 in accordance with aspects of the present invention. The thermal transfer device 36 includes a p-type leg 38 and an n-type leg 40 configured to generate power by maintaining a temperature gradient between a first substrate 42 and a second substrate 44. In this embodiment, the p-type and n-type legs 38 and 40 are coupled electrically in series and thermally in parallel to one another. In operation, heat is pumped into the first interface 42, as represented by reference numeral 46 and is emitted from the second interface 44 as represented by reference numeral 48. As a result, an electrical voltage 50 proportional to a temperature gradient between the first substrate 42 and the second substrate 44 is generated due to a Seebeck effect that may be further utilized to power a variety of applications that will be described in detail below. Examples of such applications include, but are not limited to, use in a vehicle, a turbine and an aircraft engine. Additionally, such thermoelectric devices may be coupled to photovoltaic or solid oxide fuel cells that generate heat including low-grade heat and high-grade heat thereby boosting overall system efficiencies. It should be noted that a plurality of thermocouples having the p-type and n-type thermoelements 38 and 40 may be employed based upon a desired power generation capacity of the power generation system 34. Further, the plurality of thermocouples may be coupled electrically in series, for use in a certain application.

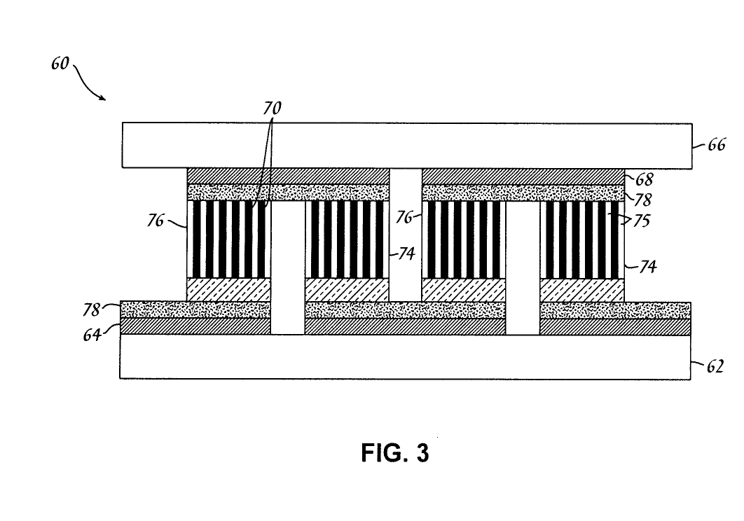

FIG. 3 illustrates a cross-sectional view of an exemplary configuration 60 of the thermal transfer device of FIGS. 1 and 2. The thermal transfer device or unit 60 includes a first thermally conductive substrate 62 having a first patterned electrode 64 disposed on the first thermally conductive substrate 62. The thermal transfer device 60 also includes a second thermally conductive substrate 66 having a second patterned electrode 68 disposed thereon. In this embodiment, the first and second thermally conductive substrates 62 and 66 comprise a thermally conductive and electrically insulating ceramic. However, other thermally conductive and electrically insulating materials may be employed for the first and second thermally conductive substrates 62 and 66. For example, electrically insulating aluminum nitride or silicon carbide ceramic may be used for the first and second thermally conductive substrates 62 and 66. In certain embodiments, the patterned electrodes 64 and 68 include a metal such as aluminum, copper and so forth. In certain embodiments, the patterned electrodes may include highly doped semiconductors. Further, the patterning of the electrodes 64 and 68 on the first and second thermally conductive substrates 62 and 66 may be achieved by utilizing techniques such as etching, photoresist patterning, shadow masking, lithography, or other standard patterning techniques. In a presently contemplated configuration, the first and second thermally conductive substrates 62 and 66 are arranged such that the first and second patterned electrodes 64 and 68 form an electrically continuous circuit.

Moreover, a plurality of thermoelements (i.e., thermoelectric elements) 74 and 76 are established between the first and second patterned electrodes 64 and 68. Further, each of the plurality of thermoelements 74 and 76 comprises an array (i.e., a plurality) of nanotubes 70 comprised of a thermoelectric material, wherein the material is a doped semiconductor material, and where thermoelements 74 comprise nanotubes of p-doped material and thermoelements 76 comprise nanotubes of n-doped material (or vice versa). Examples of suitable thermoelectric materials include, but are not limited to, InP, InAs, InSb, silicon germanium based alloys, bismuth antimonide based alloys, lead telluride based alloys (e.g., PbTe), bismuth telluride based alloys (e.g., Bi₂Te₃), or other III-V, IV, IV-VI, and II-VI semiconductors, or any combinations thereof having substantially high thermoelectric figure-of-merit, and their combinations thereof. Typically, the thermoelements 74 and 76 further comprise a porous template 75 in which the nanotubes 70 have been electrodeposited. Such porous templates may optionally comprise a substrate 72.

Regarding the template 75, the template material is not particularly limited save for the requirement that it accommodate pores. Suitable materials include, but are not limited to, anodized aluminum oxide (AAO), nanochannel glass, self-organized di-block copolymers, and the like. Typically, the template is a substantially two-dimensional planar template. The pores are substantially aligned (with respect to each other) and generally perpendicular to the plane of the template. In some embodiments the pores are roughly cylindrical in shape and generally possess a diameter between about 5 nm and about 500 nm. The template thickness is generally between about 10 μm and about 500 μm. Pore density within the template is generally between about 10⁹/cm² and about 10¹²/cm².

Regarding the nanotubes 70, the nanotubes are generally electrochemically-deposited in the pores of the template 75 (vide infra). Consequently, their dimensions and density within the template array largely parallel that of the pores. They generally possess an outer diameter between about 5 nm and about 500 nm, and a tube wall thickness between about 1 nm and about 20 nm. Their height is generally between about 10 μm and about 500 μm, and their density within the template is generally between about 10⁹/cm² and about 10¹²/cm². As mentioned above, compositionally, the nanotubes 70 comprise a doped semiconducting material, the bulk of which can include, but is not limited to, InP, InAs, InSb, silicon germanium based alloys, bismuth antimonide based alloys, lead telluride based alloys (e.g., PbTe), bismuth telluride based alloys (e.g., Bi₂Te₃), or other III-V, IV, IV-VI, and II-VI semiconductors, or any combinations thereof having substantially high thermoelectric figure-of-merit (including, e.g., ternary and quaternary semiconductors), and their combinations thereof. Within a particular thermoelement (i.e., a nanotube array), the nanotubes will comprise either a n-doped or a p-doped semiconducting composition. The nanotubes can be deposited by electrochemical codeposition, where a compound material is deposited from one solution. Alternatively, the nanotubes can be deposited by electrochemical atomic layer epitaxy (ECALE), where a monolayer or sub-monolayer of each element is deposited sequentially from separate baths. In order to obtain smooth films with excellent control over the film thickness, ECALE offers significant advantages over codeposition. See Stickney et al for examples of ECALE of thin films (Stickney et al., “Electrochemical atomic layer epitaxy,” Electroanalytical Chemistry, vol. 21, pp. 75-209, 1999).

The thermal transfer device 60 also includes a joining material 78 disposed between the plurality of thermoelements 74 and 76 and the first and second patterned electrodes 64 and 68 for reducing the electrical and thermal resistance of the interface. In certain embodiments, the joining material 78 between the thermoelements 74 and 76 and the first patterned electrode 64 may be different than the joining material 78 between the thermoelements 74 and 76 and the second patterned electrode 68. In one embodiment, the joining material 78 includes silver epoxy. It should be noted that other conductive adhesives may be employed as the joining material 78. In particular, the joining material 78 is disposed between the substrate 72 and the patterned electrode 64.

In some other embodiments, the thermoelements 74 and 76 may be bonded to the patterned electrodes 64 and 68 by diffusion bonding through atomic diffusion of materials at the joining interface or other techniques such as wafer fusion bonding for semiconductor interfaces. As will be appreciated by one skilled in the art, diffusion bonding causes micro-deformation of surface features leading to sufficient contact on an atomic scale to cause the two materials to bond. In certain embodiments, gold may be employed as an interlayer for the bonding and the diffusion bonds may be achieved at relatively low temperatures of about 300° C. In certain other embodiments indium or indium alloys may be employed as an interlayer for the bonding at temperatures of about 100° C. to about 150° C. Further, a typical solvent cleaning step may be applied on the surfaces to achieve flat and clean surfaces for applying diffusion bonding. Examples of solvents for the cleaning step include acetone, isopropanol, methanol and so forth. Further, metal coatings may be disposed on the top and bottom surfaces of the thermoelements 74 and 76 and the substrate 72 to facilitate the bonding between the thermoelements and the first and second substrates 62 and 66. In one embodiment, the thermoelements 74 and 76 may be bonded to the patterned electrodes 64 and 68 through direct diffusion bonding. Alternatively, the thermoelements 74 and 76 may be bonded to the patterned electrodes 64 and 68 via an interlayer, such as gold, metal, or solder metal alloy foil. In certain embodiments, the bonding between the thermoelements 74 and 76 and the first and second substrates 62 and 66 may be achieved through an interface layer such as silver epoxy. However, other joining methods may be employed to achieve the bonding between the thermoelements 74 and 76 and the first and second substrates 62 and 66.

While not intending to be bound by theory, in a presently contemplated configuration, the thermoelements 74 and 76 comprise nanotubes having wall thicknesses where quantum effects (e.g., quantum or surface confinement) are dominant. Typically, this involves wall thicknesses between about 1 nm and about 20 nm. Further, the electronic density of states of the charge carriers and phonon transmission characteristics can be controlled by altering the dimensions and composition of the nanotubes within thermoelements 74 and 76, thereby enhancing the efficiency of the thermoelectric devices that is characterized by the figure-of-merit (ZT) of the thermoelectric device.

In some embodiments, the thermal transfer device of FIGS. 1-3 may include multiple layers, each of the layers having a plurality of thermoelements to provide appropriate materials composition and doping concentrations to match the temperature gradient between the hot and cold sides for achieving maximum ZT and efficiency.

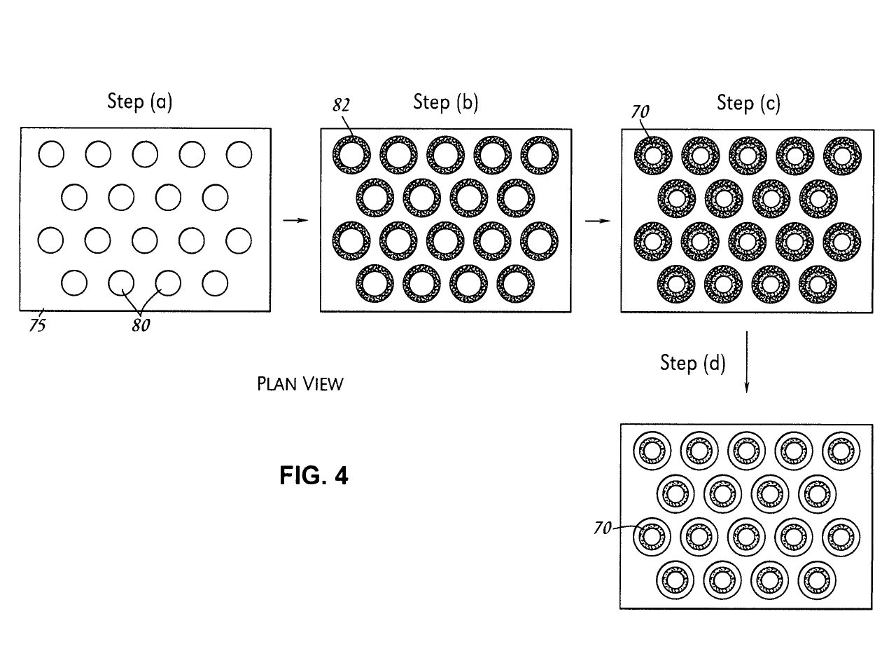

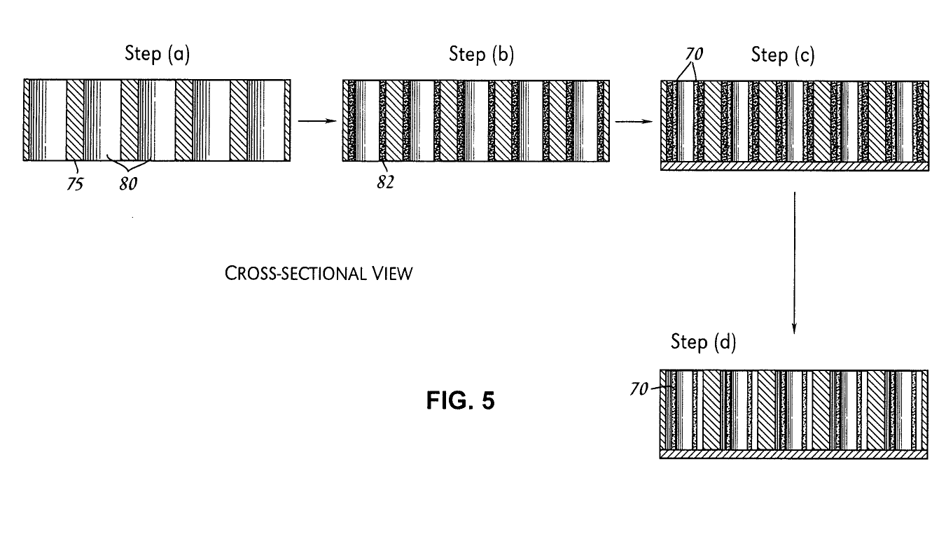

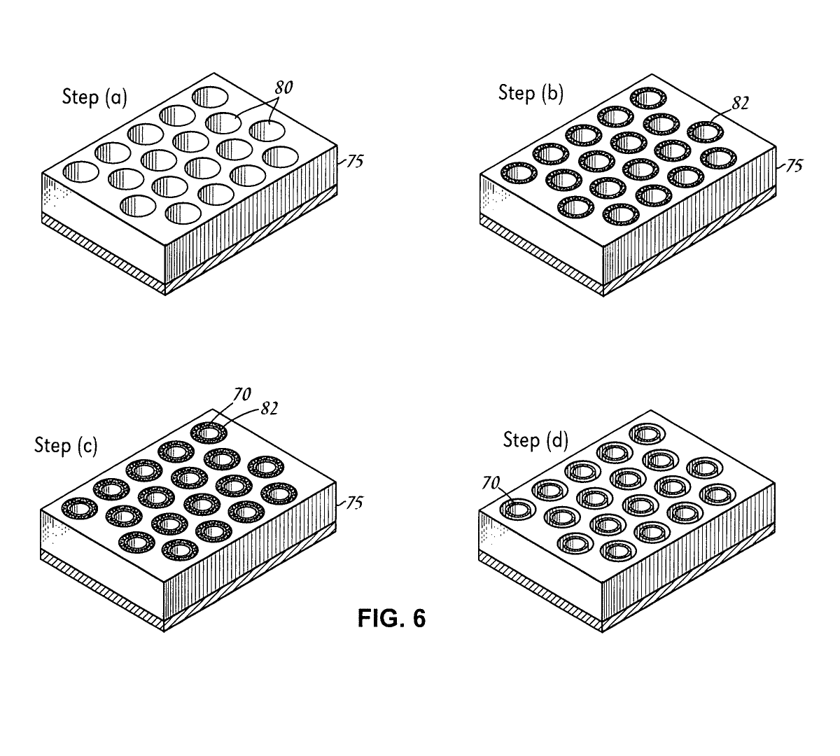

FIGS. 4-6 relate to methods of making the thermoelements 74 and 76 described above. Referring to FIG. 4, such methods comprise the steps of: (Step (a)) providing a substantially planar porous template 75 comprising a plurality of pores 80, the pores being largely perpendicular to the plane of the template and comprising pore walls that extend the thickness of the template; (Step (b)) uniformly depositing a metal layer 82 over porous template such that the pore walls are coated; (Step (c)) using the coated pore walls to electrochemically deposit thermoelectric material as nanotubes 70 within the pore walls; and (Step (d)) selectively etching away the metal layer to yield a plurality of thermoelectric nanotubes in the template. Steps (a)-(d) of FIGS. 5 and 6 correspond to cross-sectional and perspective views, respectively, of the steps shown in FIG. 4.

The metal layer can be any metal or combination of metals that can be conformally deposited over the template surface so as to serve as an electrode for the electrodeposition of thermoelectric nanotubes within the pores. Suitable materials include, but are not limited to, gold (Au), copper (Cu), nickel (Ni), and combinations thereof. Typically, this metal layer is deposited via electroless means, and the layer generally has a thickness between about 10 nm and about 100 nm. Removal of the metal layer after nanotube deposition can be accomplished by selective etching techniques such as, but not limited to, wet chemical etching of gold by a potassium iodide/iodine solution, wet chemical etching of copper or nickel by an iron chloride solution, or dry etching processes, and the like. For a general (non-specific) discussion of electrochemical deposition of metal in a porous (polymer) membrane, see Ku et al. “Fabrication of Nanocables by Electrochemical Deposition Inside Metal Nanotubes,” J. Am. Chem. Soc. vol. 126, pp. 15022-15023, 2004. See above for details on the template and nanotube materials. Alternatively, the metal can be deposited by a vapor phase process, such as atomic layer deposition (ALD). ALD could be used to deposit a metal layer on the nanoporous template, such as copper, iron, nickel, gold, etc., or another type of conducting material that could act as an electrode, such as indium tin oxide. These vapor deposited electrodes could be removed after depositing the thermoelectric material by a wet or dry selective chemical etch. For an example of nanotubes deposited by ALD onto anodic alumina templates see Elam et al., “Conformal Coating on Ultrahigh-Aspect-Ratio Nanopores of Anodic Alumina by Atomic Layer Deposition,” Chem. Mater. vol. 15, pp. 3507-3517, 2003).

In some embodiments, it is envisioned that an entirely metal template is utilized instead of a ceramic template covered by a metal layer. In such an embodiment, the entire metal template would have to be removed after nanotube deposition and replaced by an insulating material, such as a ceramic or polymer, in order to provide mechanical stability.

In some or other embodiments, the nanotubes 70 are formed using a variation on one or more of the above-described embodiments or using a method other than those described above. For example, in some embodiments the nanotubes are deposited by electrodeposition in templates coated not with a metal layer, but rather having pore walls coated with a metal nanoparticle seed layer or functional molecular layer. See, e.g., Brumlik et al., “Template Synthesis of Metal Microtubules,” J. Am. Chem. Soc., vol. 113, pp. 3174-3175, 1991. In other embodiments, very fast electrodeposition can result in the deposition of nanotubes in porous templates rather than nanowires. See, e.g., Yuan et al. “Highly Ordered Platinum-Nanotubule Arrays for Amperometric Glucose Sensing,” Adv. Funct. Mater., vol. 15(5), pp. 803-809, 2005. In some or other embodiments, the electrode layer only partially coats one side of the template pores, thereby permitting electrochemical deposition of nanotubes within the pores. See, e.g., Li et al., “A Facile Route to Fabricate Single-crystalline Antimony Nanotube Arrays,” Chem. Lett., vol. 34(7), pp. 930-931, 2005; Lee et al., “A Template-Based Electrochemical Method for the Synthesis of Multisegmented Metallic Nanotubes,” Angew. Chem. Int. Ed., vol. 44, pp. 6050-6054, 2005. In still other embodiments, templates are coated with a sacrificial layer (e.g., carbon nanotubes or polymer) and filled with metal nanowires. The sacrificial layer is then removed and nanotubes are electrodeposited in the resulting open spaces of the template. See, e.g., Mu et al., “Uniform Metal Nanotube Arrays by Multistep Template Replication and Electrodeposition,” Adv. Mater., vol. 16, pp. 1550-1553, 2004.

In fabricating such above-mentioned thermoelements, in some embodiments a particular doping density within the nanotubes is chosen for particular thermoelectric performance (typically, such doping densities are ca. 10¹⁷-10¹⁸ cm⁻³). The doping can be accomplished by intrinsic doping to produce an excess of one of the elements of the compound. For example, an excess of Te in Bi₂Te₃ deposition results in an n-type material (see, e.g., Yoo et al., “Electrochemically deposited thermoelectric n-type Bi₂Te₃ thin films,” Electrochimica Acta vol. 50(22), pp. 4371-4377, 2005). An excess of one of the elements can be obtained, for example, by altering the electrodeposition conditions, including deposition potential. Alternatively, an extrinsic dopant can be introduced into the nanotubes by adding a small amount of a dopant precursor to the electrochemical deposition solution or by integrating a cycle into the deposition process for the dopant.

As mentioned above, the critical dimension with respect to thermoelectric properties in the above-described nanotubes is the tube wall thickness. By depositing the nanotube walls using a controlled deposition process, the nanotube wall thickness can be controlled with sub-nanometer resolution. Because the nanotube wall thickness is the critical dimension, any distribution in the pore diameters in the template will be fairly unimportant (this is in contrast to conformal deposition of nanowires in porous templates, where larger wires will tend to dominate the device behavior). It is also not necessary to fabricate templates with very small pore diameters (e.g., <10 nm). Since the critical dimension is the wall thickness, it is possible to have outer tube diameters (corresponding to template pore diameters) with larger, and more easily fabricated dimensions (e.g., >10 nm). Again, this is an advantage compared to nanowires, where conformal deposition would require fabrication of templates with pore diameters corresponding to the critical thermoelectric property dimensions, which are typically less than 10-20 nm. Because the thermoelectric material deposits as a thin film over the entire surface simultaneously, the composition of the deposit can be carefully controlled. This avoids the potential problems of variation in composition along the length of a nanowire, which are anticipated for very high aspect ratio nanowire deposition, e.g., <10 nm diameter by >100 um tall. By depositing the nanotubes conformally over the surface of the template, it is possible to obtain nanotubes in nearly 100% of the pores. This avoids any difficulties that may be encountered for the deposition of nanowires, where obtaining high pore filling ratios is potentially difficult for high aspect ratio structures. Additionally, such electrochemical deposition techniques are easily scalable.

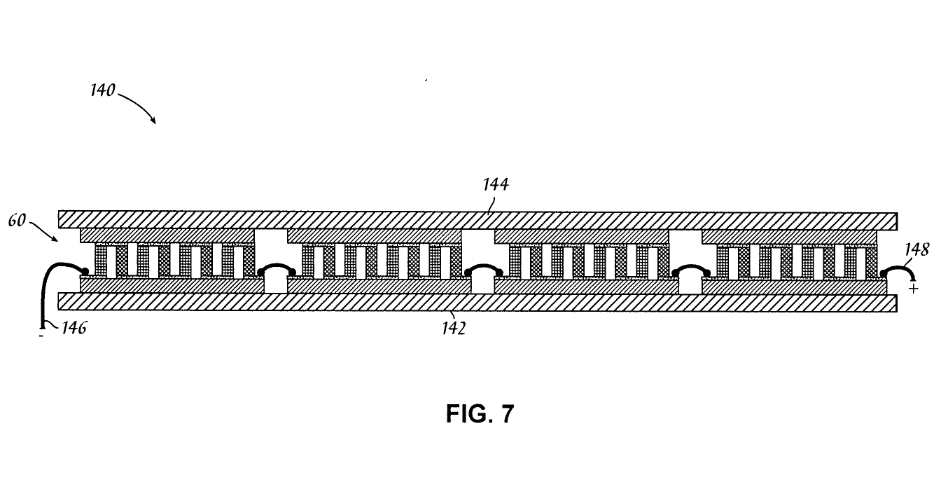

FIG. 7 illustrates a cross-sectional side view of a thermal transfer device or an assembled module 140 having a plurality of thermal transfer devices or thermal transfer units 60 in accordance with embodiments of the present technique. In the illustrated embodiment, the thermal transfer units 60 are mounted between opposite substrates 142 and 144 and are electrically coupled to create the assembled module 140. In this manner, the thermal transfer devices 60 cooperatively provide a desired heating or cooling capacity, which can be used to transfer heat from one object or area to another, or provide a power generation capacity by absorbing heat from one surface at higher temperatures and emitting the absorbed heat to a heat sink at lower temperatures. In certain embodiments, the plurality of thermal transfer units 60 may be coupled via a conductive joining material, such as silver filled epoxy or a metal alloy. The conductive joining material or the metal alloy for coupling the plurality of thermal transfer devices 60 may be selected based upon a desired processing technique and a desired operating temperature of the thermal transfer device. Finally, the assembled module 60 is coupled to an input voltage source via leads 146 and 148. In operation, the input voltage source provides a flow of current through the thermal transfer units 60, thereby creating a flow of charges via the thermoelectric mechanism between the substrates 142 and 144. As a result of this flow of charges, the thermal transfer devices 60 facilitate heat transfer between the substrates 142 and 144. Similarly, the thermal transfer devices 60 may be employed for power generation and/or heat recovery in different applications by maintaining a thermal gradient between the two substrates 142 and 144.

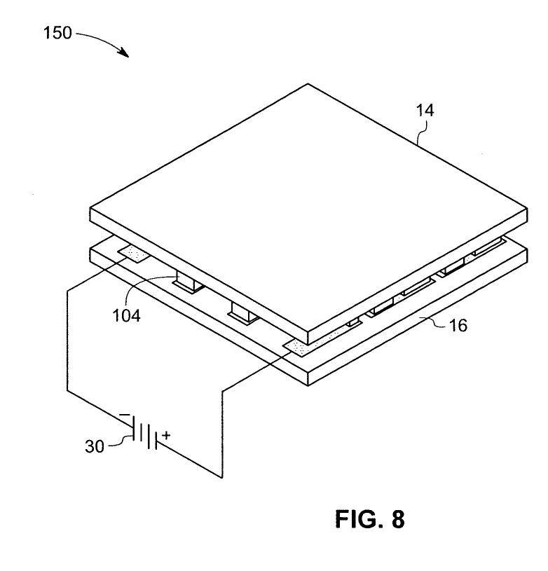

FIG. 8 illustrates a perspective view of a thermal transfer module 150 having an array of thermal transfer thermoelements 104 in accordance with embodiments of the present technique. In this embodiment, the thermal transfer devices 104 are employed in a two-dimension array to meet a thermal management need of an environment or application. The thermal transfer devices 104 may be assembled into the heat transfer module 150, where the devices 104 are coupled electrically in series and thermally in parallel to enable the flow of charges from the first object 14 in the module 150 to the second object 16 thereby facilitating heat transfer between the first and second objects 14 and 16 in the module 150. It should be noted that the voltage source 30 may be a voltage differential that is applied to achieve heating or cooling of the first or second objects 14 and 16. Alternatively, the voltage source 30 may represent an electrical voltage generated by the module 150 when used in a power generation application.

Various aspects of the techniques described above find utility in a variety of heating/cooling systems, such as refrigeration, air conditioning, electronics cooling, industrial temperature control, and so forth. The thermal transfer devices as described above may be employed in air conditioners, water coolers, climate controlled seats, and refrigeration systems including both household and industrial refrigeration. For example, such thermal transfer devices may be employed for cryogenic refrigeration, such as for liquefied natural gas (LNG) or superconducting devices. Further, the thermal transfer devices as described above may be employed for cooling of components in various systems, such as, but not limited to vehicles, turbines and aircraft engines. For example, a thermal transfer device may be coupled to a component of an aircraft engine such as, a fan, or a compressor, or a combustor or a turbine case. An electric current may be passed through the thermal transfer device to create a temperature differential to provide cooling of such components.

Alternatively, the thermal transfer device described herein may utilize a naturally occurring or manufactured heat source to generate power. For example, the thermal transfer devices described herein may be used in conjunction with geothermal based heat sources where the temperature differential between the heat source and the ambient (whether it be water, air, etc.) facilitates power generation. Similarly, in an aircraft engine the temperature difference between the engine core air flow stream and the outside air flow stream results in a temperature differential through the engine casing that may be used to generate power. Such power may be used to operate or supplement operation of sensors, actuators, or any other power applications for an aircraft engine or aircraft. Additional examples of applications within which thermoelectric devices described herein may be used include gas turbines, steam turbines, vehicles, and so forth. Such thermoelectric devices may be coupled to photovoltaic or solid oxide fuel cells that generate heat thereby boosting overall system efficiencies.

The thermal transfer devices described above may also be employed for thermal energy conversion and for thermal management. It should be noted that the materials and the manufacturing techniques for the thermal transfer device may be selected based upon a desired thermal management need of an object. Such devices may be used for cooling of microelectronic systems such as microprocessor and integrated circuits. Further, the thermal transfer devices may be employed for thermal management of semiconductor devices, photonic devices, and infrared sensors.

The following examples are included to demonstrate particular embodiments of the present invention. It should be appreciated by those of skill in the art that the methods disclosed in the examples that follow merely represent exemplary embodiments of the present invention. However, those of skill in the art should, in light of the present disclosure, appreciate that many changes can be made in the specific embodiments described and still obtain a like or similar result without departing from the spirit and scope of the present invention.

### EXAMPLE 1

This Example serves to illustrate the formation of thermoelectric elements comprising nanotubes for use in thermoelectric devices, in accordance with some embodiments of the present invention.

A nanoporous alumina template is fabricated by anodization of aluminum foil. The pores created during the anodization are nearly parallel to one another and run through the length of the template. The average pore diameter and spacing are determined by the anodization conditions, including potential, acid, etc. (this is a well-established procedure). The pores of the anodized alumina membrane are coated by gold metal using an electroless plating process (Kohli et al., “Template Synthesis of Gold Nanotubes in an Anodic Alumina Membrane,” J. Nanosci. Nanotech. vol. 4, pp. 605-610, 2003). Next, one side of the membrane is coated with a thick gold electrode layer by fast electroless plating. The membrane is then placed into an electrochemical flow cell, and thermoelectric nanotubes are deposited concentrically onto the gold nanotubes of the membrane. The thermoelectric material is deposited by an electrochemical atomic layer epitaxy process. For example, Bi₂Te₃ can be deposited by using a modification of the procedure described by Zhu et al., “Optimization of the formation of bismuth telluride thin film using ECALE,” J. Electroanalytical Chemistry, 585, 83-88, 2005. In that case, they deposited thin films. In order to deposit a film over the surface of the high aspect ratio gold nanotubes, it may be necessary to increase the deposition cycle times, etc. After thermoelectric nanotube deposition, metal films are deposited onto one or both sides of the membrane. Then the gold nanotubes are removed by a selective chemical etch. The remaining structure comprises thermoelectric nanotubes embedded in the pores of the nanoporous alumina template and connected at the top and bottom sides by deposited metal layers.

### EXAMPLE 2

This Example serves to illustrate how a plurality of thermoelectric elements, comprising electrochemically-deposited nanotubes, can be integrated into the manufacture of a thermoelectric device, in accordance with some embodiments of the present invention.

Metal electrodes (Cu or Al) are patterned on two thermally conductive substrates (AlN or SiC) using standard photolithography. The metal electrodes are patterned on each substrate so that when the two substrates are facing each other with thermoelectric elements in between, the electrodes and thermoelectric elements are electrically in series from one corner of the first substrate to the opposite corner of the second substrate. To connect the thermoelements to the metal electrodes, indium foil is used as a joining layer. Pieces of indium foil are sandwiched between the metal electrodes and the thermoelements, and then the entire substrate/thermoelement assembly is subjected to pressure and heat to cause the indium foil to diffusion bond between the metal electrodes on the substrates and the metal layers on the ends of each of the thermoelements. In this final thermoelectric module, the patterned electrodes on each substrate are electrically connected in series with the joining layers and alternating n-type and p-type thermoelements sandwiched between the two substrates. The thermoelements are thermally connected in parallel between the two substrates.

It will be understood that certain of the above-described structures, functions, and operations of the above-described embodiments are not necessary to practice the present invention and are included in the description simply for completeness of an exemplary embodiment or embodiments. In addition, it will be understood that specific structures, functions, and operations set forth in the above-described referenced patents and publications can be practiced in conjunction with the present invention, but they are not essential to its practice. It is therefore to be understood that the invention may be practiced otherwise than as specifically described without actually departing from the spirit and scope of the present invention as defined by the appended claims.

What is claimed is:

1. A thermoelectric device comprising:
a) a first thermally conductive substrate having a first patterned electrode disposed thereon;
b) a second thermally conductive substrate having a second patterned electrode disposed thereon, wherein the first and second thermally conductive substrates are arranged such that the first and second patterned electrodes are connected to form a continuously electrical circuit;
c) a plurality of thermoelectric elements positioned between the first and second patterned electrodes, wherein the thermoelectric elements comprise a plurality of nanotube structures of doped semiconducting material; and
d) a joining material disposed between the plurality of thermoelectric elements and at least one of the first and second patterned electrodes.

2. The thermoelectric device of claim 1, wherein the first and second thermally conductive substrates comprise an electrically insulating aluminum nitride ceramic, or an electrically insulating silicon carbide material.

3. The thermoelectric device of claim 1, wherein the doped semiconducting material of which the nanotubes are formed comprises a bulk thermoelectric material selected from the group consisting of InAs, InSb, InP, silicon germanium based alloys; bismuth antimony based alloys; lead telluride based alloys; bismuth telluride based alloys; III-V, IV, V, IV-VI, and II-VI semiconductors; and combinations thereof.

4. The thermoelectric device of claim 1, wherein the doped semiconducting material of which the nanotubes are formed is a doped group III-V semiconductor selected from the group consisting of InP, InAs, InSb, and combinations thereof.

5. The thermoelectric device of claim 1, wherein the plurality of nanotubes of which a particular thermoelectric element is comprised reside within a porous template.

6. The thermoelectric device of claim 5, wherein the porous template is selected from the group consisting of anodized aluminum oxide, nanochannel glass, self-organized block copolymers, and combinations thereof.

7. The thermoelectric device of claim 1, wherein each of the plurality of thermoelectric elements comprise nanotubes of substantially either p-type material or n-type material.

8. The thermoelectric device of claim 1, wherein the plurality of thermoelectric elements are organized into a plurality of thermal transfer units, wherein the plurality of thermal transfer units are electrically coupled between opposite substrates.

9. The thermoelectric device of claim 6, wherein the nanotubes are formed in the porous template by an electrochemical means.

10. The thermoelectric device of claim 9, wherein the nanotubes are deposited by a method selected from the group consisting of electrochemical codeposition, electrochemical atomic layer epitaxy, and combinations thereof

11. The thermoelectric device of claim 1, wherein the nanotubes comprise a wall thickness of from at least about 1 nm to at most about 20, and an outer diameter of from at least about 5 nm to at most about 500 nm.

12. The method of claim 1, wherein the nanotubes comprise a length of from at least about 10 μm to at most about 500 μm.

13. The thermoelectric device of claim 1, wherein the device is configured to generate power by substantially maintaining a temperature gradient between the first and second thermally conductive substrates.

14. The thermoelectric device of claim 1, wherein introduction of current flow between the first and second thermally conductive substrates enables heat transfer between the first and second thermally conductive substrates via a flow of charge between the first and second thermally conductive substrates.

15. The thermoelectric device of claim 1, wherein the thermoelectric elements are connected electrically in series and thermally in parallel.

16. The thermoelectric device of claim 1, wherein the device is an integral part of a system selected from the group consisting of a vehicle, a power source, a heating system, a cooling system, and combinations thereof.

17. A method for fabricating a thermoelectric element, the method comprising the steps of:
a) providing a substantially planar porous template having a thickness and comprising a plurality of pores, the pores being largely perpendicular to the plane of the template and comprising pore walls that extend the thickness of the template;
b) uniformly depositing a metal layer over porous template such that the pore walls are coated;
c) using the coated pore walls to electrochemically deposit thermoelectric material as nanotubes within the pore walls; and
d) selectively etching away the metal layer to yield a plurality of thermoelectric nanotubes in the template.

18. The method of claim 17, wherein the porous template comprises a material selected from the group consisting of anodized aluminum oxide, nanochannel glass, self-organized block copolymers, and combinations thereof.

19. The method of claim 17, wherein the metal layer comprises a metal selected from the group consisting of Cu, Au, Ni, and combinations thereof.

20. The method of claim 17, wherein the metal layer is deposited by an electroless process.

21. The method of claim 17, wherein the metal layer is deposited by an atomic layer deposition process.

22. The method of claim 17, wherein the thermoelectric material of which the nanotubes are comprised is a doped semiconductor material, the bulk material selected from the group consisting of InAs, InSb, InP, silicon germanium based alloys; bismuth antimony based alloys; lead telluride based alloys; bismuth telluride based alloys; III-V, IV, V, IV-VI, and II-VI semiconductors; and combinations thereof.

23. The method of claim 17, wherein the nanotubes comprise a wall thickness of from at least about 1 nm to at most about 20 nm, and an outer diameter of from at least about 5 nm to at most about 500 nm.

24. The method of claim 17, wherein the nanotubes comprise a length of from at least about 10 μm to at most about 500 μm.

25. The method of claim 17, wherein the metal layer is etched away via a selective etching process selected from the group consisting of wet chemical etching, dry chemical etching, and combinations thereof.

26. The method of claim 17, wherein the porous template resides on a substrate.

27. A method of manufacturing a thermoelectric device, the method comprising the steps of:
a) providing a first thermally conductive substrate having a first patterned electrode disposed thereon;
b) providing a second thermally conductive substrate having a second patterned electrode disposed thereon;
c) establishing a plurality of thermoelectric elements positioned between the first and second patterned electrodes, wherein the thermoelectric elements comprise a plurality of nanotubes, and wherein the thermoelectric elements are fabricated in accordance with the method of claim 17; and
d) disposing a joining material between the plurality of thermoelectric elements and the first and second patterned electrodes.

28. The method of claim 27, wherein the first and second thermally conductive substrates comprise an electrically insulating aluminum nitride ceramic, or an electrically insulating silicon carbide material.

29. The method of claim 27, wherein the nanotubes are composed of a thermoelectric material largely selected from the group consisting of silicon germanium based alloys; bismuth antimony based alloys; lead telluride based alloys; bismuth telluride based alloys; III-V, IV, V, IV-VI, and II-VI semiconductors; and combinations thereof.

30. The method of claim 27, wherein the nanotubes are composed of a group III-V semiconductor selected from the group consisting of InP, InAs, InSb, and combinations thereof.

31. The method of claim 27, wherein the plurality of nanotubes of which a particular thermoelectric element is comprised reside within a porous template.

32. The method of claim 27, wherein each of the plurality of thermoelectric elements largely comprises nanotubes of either p-type material or n-type material.

33. A system comprising:
a) a heat source;
b) a heat sink; and
c) a thermoelectric device coupled between the heat source and the heat sink and configured to provide cooling or to generate power, the device comprising;
i) a first thermally conductive substrate having a first patterned electrode disposed thereon;
ii) a second thermally conductive substrate having a second patterned electrode disposed thereon, wherein the first and second thermally conductive substrates are arranged such that the first and second patterned electrodes are connected to form a continuously electrical circuit;
iii) a plurality of thermoelectric elements positioned between the first and second patterned electrodes, wherein the thermoelectric elements comprise a plurality of nanotubes; and
iv) a joining material disposed between the plurality of thermoelectric elements and at least one of the first and second patterned electrodes.

34. The system of claim 33, wherein the first and second thermally conductive substrates comprise an electrically insulating aluminum nitride ceramic, or an electrically insulating silicon carbide material.

35. The system of claim 33, nanotubes are composed of a thermoelectric material largely selected from the group consisting of silicon germanium based alloys; bismuth antimony based alloys; lead telluride based alloys; bismuth telluride based alloys; III-V, IV, V, IV-VI, and II-VI semiconductors; and combinations thereof.

36. The system of claim 33, wherein the plurality of nanotubes of which a particular thermoelectric element is comprised reside within a porous template.

37. The system of claim 33, wherein each of the plurality of thermoelectric elements comprises nanotubes of substantially either p-type material or n-type material.

38. The system of claim 33, wherein the thermoelectric elements are fabricated according to the method of claim 17.

39. A method of manufacturing a thermoelectric device, the method comprising the steps of:
a) providing a first thermally conductive substrate having a first patterned electrode disposed thereon;
b) providing a second thermally conductive substrate having a second patterned electrode disposed thereon;
c) establishing a plurality of thermoelectric elements positioned between the first and second patterned electrodes, wherein the thermoelectric elements comprise a plurality of nanotubes; and
d) disposing a joining material between the plurality of thermoelectric elements and the first and second patterned electrodes.

40. The method of claim 39, wherein the first and second thermally conductive substrates comprise an electrically insulating aluminum nitride ceramic, or an electrically insulating silicon carbide material.

41. The method of claim 39, wherein the nanotubes are composed of a thermoelectric material largely selected from the group consisting of silicon germanium based alloys; bismuth antimony based alloys; lead telluride based alloys; bismuth telluride based alloys; III-V, IV, V, IV-VI, and II-VI semiconductors; and combinations thereof.

42. The method of claim 39, wherein the nanotubes are composed of a group III-V semiconductor selected from the group consisting of InP, InAs, InSb, and combinations thereof.

43. The method of claim 39, wherein the plurality of nanotubes of which a particular thermoelectric element is comprised reside within a porous template.

44. The method of claim 39, wherein each of the plurality of thermoelectric elements largely comprises nanotubes of either p-type material or n-type material.
